(19) United States
(12) Patent Application Publication
(10) Pub. No.: US 2008/0010034 A1
(43) Pub. Date: Jan. 10, 2008

(54) Method for network analyzer calibration and network analyzer

(76) Inventor: Takashi Yamasaki, Hyogo (JP)

Correspondence Address: Paul D. Greeley, Esq.;Ohlandt, Greeley, Ruggiero & Perle, L.L.P., One Landmark Square, 10th Floor, Stamford, CT, 06901-2682, US

(21) Appl. No.: 11/820,761

(22) Filed: Jun. 20, 2007

(30) Foreign Application Priority Data
Jul. 5, 2006 (JP) 2006-185967

(51) Int. Cl. G01R 35/00; G01R 27/00; G06F 19/00

(52) U.S. Cl. 702/85; 324/600; 324/601

(57) ABSTRACT

An adapter of unknown properties necessary for performing simple N-port calibration is prepared and simple N-port calibration is performed on a network analyzer using the adapter. Moreover, the open reference, short reference, and load reference are measured in succession, with the adapter in a disassembled state, at the test ports to which the adapter was connected during calibration. Finally, the calibration coefficient obtained by simple N-port calibration is corrected using the properties of the adapter found from the measured values of each reference. N is an integer of two or more.

### BACKGROUND

1. Field of the Disclosure

The present disclosure relates to technology for the calibration of a network analyzer. The present disclosure is particularly ideal for network analyzers that measure non-insertable devices.

2. Discussion of the Background Art

When measuring the through connection properties for calibration of a network analyzer, it is usually necessary to directly connect test ports together and bring the through length to zero. When the device under test is an insertable device, a through pass of length zero is obtained by directly connecting the test ports together. The device under test is hereafter referred to as a DUT. On the other hand, when the DUT is a non-insertable device, there is at least one combination of test ports wherein the test ports cannot be directly connected together. Therefore, a method other than the usual method is used to calibrate the network analyzer when the DUT is a non-insertable device. Examples of such calibration methods are the port extension method, the swap equal adapters method (refer to Applying Error Correction to Network Analyzer Measurements, (US), Agilent AN 1287-3, Application Note, Agilent Technologies, Inc., p. 13), the adapter removal method (refer to Measuring Non-Insertable Devices, (US) Agilent 8510-13, Product Note, Agilent Technologies, Inc., pp. 8-9), the method whereby the adapter is used as the through reference (refer to Agilent, E5070B/E5071B ENA Series RF Network Analyzers User's Guide, Agilent Technologies, Inc., pp. 150-154), and the method for removing known adapter properties using a de-embedding function (refer to JP Unexamined Patent Publication (Kokai) 11-352,163 (page 6, FIG. 10) and Techniques for VNA Measurements of Non-Insertable Devices, Anritsu Corporation, pp. 4-5).

Several of the above-mentioned methods will be described briefly. First, the port extension method is a method whereby the port is extended with the electrical length of the adapter and the effect of the extension is eliminated. The adapter removal method is the method that uses the results of full two-port calibration employing the adapter that will be inserted between two specific test ports connected to one of the test ports and the results of full two-port calibration with the same adapter connected to the other test port. The method whereby the adapter is used as the through reference is generally conducted by the following four steps. (1) First, one-port calibration is performed on the test port to which the adapter is connected. (2) Then the adapter is connected to the test port where calibration has been performed. Furthermore, open reference, short reference, and load reference are connected in succession to the same adapter and each reference is measured, through the adapter, at the test ports where calibration has been conducted. (3) The circuit parameters of the adapter (for instance, the S parameter) are calculated. (4) Finally, full N-port calibration is performed on N number of test ports used to measure the DUT. A network analyzer is configured so that the previously determined adapter circuit parameters are used as the circuit parameters for the through reference between the test ports to which the adapter will be connected.

See also JP Unexamined Patent Publication (Kokai) 2005-331,519, JP Unexamined Patent Publication (Kokai) 11-38,054 (pages 2 and 3, FIG. 7, FIG. 10), and Agilent E5070B/E5071B Series RF Network Analyzers User's Guide, Agilent Technologies, Inc., pp. 145-147.

However, the calibration by the port extension method and the swap equal adapters method is not as precise as by the other methods. Moreover, the calibration by the swap equal adapters method requires preparation of two types of adapters with very similar properties, but it is difficult to prepare such adapters. Indicating the properties and direction of the adapters require careful handling. The method whereby a de-embedding function is used requires that the properties of the adapter are known prior to calibration, but there are cases in which it is difficult to obtain these properties. Calibration by the adapter removal method requires (2x_{N}C₂) set full two-port calibration within an N-port measurement environment, and measuring with this frequency becomes a problem. Moreover, in the case of calibration by the method whereby the adapter is used as the through reference, the calibration procedure becomes more complex with an increase in the number of adapters needed for calibration. For instance, the number of settings relating to the adapter and the number of times a port is measured increases with the number of adapters. This tends to produce measurement errors. Therefore, an object of the present disclosure is to provide technology for the calibration of a network analyzer for measuring non-insertable devices that is simpler than in the past.

### SUMMARY OF THE DISCLOSURE

By means of the present disclosure, first N-port calibration is conducted on a network analyzer, and then the open reference, short reference, and load reference are measured at the calibrated test ports with or without the adapter installed. In this case, N is two or greater. Moreover, the properties of the adapter are determined from the measured values of three references and the calibration plane moves based on these properties. Specifically, the present disclosure is as follows.

The first subject of the disclosure is a method for calibrating a network analyzer having two or more test ports, this calibration method characterized in that it comprises a step for preparing an adaptor of unknown properties necessary for conducting N port calibration; a step for conducting N port calibration using the adaptor; a step for measuring, with the adaptor in a disassembled state, the open reference, short reference, and load reference at the test port to which the adaptor was connected during this calibration; and a step for correcting the calibration coefficient obtained by this calibration using the adaptor properties found from the measured values of the open reference, short reference, and load reference, wherein N is an integer of two or greater.

The second subject of the disclosure is a method for calibrating a network analyzer having three or more test ports, this calibration method characterized in that it comprises a step for preparing an adaptor of unknown properties necessary for conducting simple N port calibration; a step for conducting simple N port calibration using the adaptor; a step for measuring, with the adaptor in a disassembled state, the open reference, short reference, and load reference at the test port to which the adaptor was connected during this calibration; and a step for correcting the calibration coefficient obtained by this calibration using the adaptor properties found from the measured values of the open reference, short reference, and load reference, wherein N is an integer of three or greater.

The third subject of the disclosure is a method for calibrating a network analyzer having two or more test ports, this calibration method characterized in that it comprises a step for preparing an electronic calibration module; a step for preparing an adaptor of unknown properties that serves to connect to a port of the electronic calibration module the test ports that cannot be directly connected; a step for conducting N port calibration using the adaptor and the electronic calibration module; a step for measuring, with the adaptor in a disassembled state, the open reference, short reference, and load reference at the test port to which the adaptor was connected during this calibration; and a step for correcting the calibration coefficient obtained by this calibration using the adaptor properties found from the measured values of the open reference, short reference, and load reference, wherein N is an integer of two or greater.

The fourth subject of the disclosure is a method for calibrating a network analyzer having two or more test ports, this calibration method characterized in that it comprises a step for preparing an adaptor of unknown properties that serves to connect to a port of the device under test the test ports for measuring the device under test that cannot be directly connected; a step for conducting N port calibration with the adaptor in a disassembled state from the test port; a step for measuring, with the adaptor in an assembled state, the open reference, short reference, and load reference at the test port for which the adaptor is prepared; and a step for correcting the calibration coefficient obtained by this calibration using the adaptor properties found from the measured values of the open reference, short reference, and load reference, wherein N is an integer of two or greater.

The fifth subject of the disclosure is the calibration method according to any of the first through fourth subjects of the disclosure, further characterized in that by means of the step for correcting the calibration coefficient, the calibration coefficient is corrected by adding to the calibration coefficient the properties of a circuit with two terminal pairs (S11a, S12a, S21a, S22a) as represented by the following formula:

$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula 3\end{matrix} ]$$

wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

The sixth subject of the disclosure is a network analyzer having two or more test ports, this network analyzer characterized in having a mathematical operation means for finding the properties of the two-terminal-pair circuit from the results of measuring the open reference, short reference, and load reference at the test port where N port calibration has been conducted, wherein N is an integer of two or greater.

The seventh subject of the disclosure is the network analyzer according to the sixth subject of the disclosure, further characterized in that N port calibration is simple N port calibration or N port calibration using an electronic calibration module.

The eighth subject of the disclosure is the network analyzer according to the sixth or seventh subject of the disclosure, further characterized in that the correction of the calibration coefficient is a correction of the calibration coefficient by adding to the correction coefficient the properties of the two-terminal-pair circuit (S11a, S12a, S21a, S22a) represented by the following formula:

$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula 4\end{matrix} ]$$

wherein S11Ms, S11Mo, and S11Ml are the measured values of the short reference, the measured value of the open reference and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

By means of the present disclosure, settings relating to an adapter is unnecessary and the equipment operation is simplified when compared to the past. Moreover, the adapter is assembled and disassembled fewer times and there are fewer measurements. Furthermore, by means of the present disclosure, it is not necessary to know the adapter properties prior to calibration.

### BRIEF DESCRIPTION OF THE DRAWINGS

FIG. 1 is a drawing showing the structure of network analyzer 100.

FIG. 2 is a drawing showing network analyzer 100, as well as adapters 410 and 420.

FIG. 3 is a flow chart showing the procedure for calibrating network analyzer 100.

FIG. 4 is a drawing showing the signal flow when an anti-adapter is connected to a transmitting port.

FIG. 5 is a drawing showing the signal flow when an anti-adapter is connected to a transmitting port.

FIG. 6 is a drawing showing the signal flow when an anti-adapter is connected to a receiving port.

FIG. 7 is a drawing showing the signal flow when an anti-adapter is connected to a receiving port.

FIG. 8 is a drawing showing network analyzer 100 and electronic calibration module 500.

FIG. 9 is a flow chart showing the procedure for calibrating network analyzer 100.

FIG. 10 is a drawing showing the structure of network analyzer 200.

FIG. 11 is a flow chart showing the procedure for calibrating network analyzer 200.

### DETAILED DESCRIPTION OF THE PREFERRED EMBODIMENT

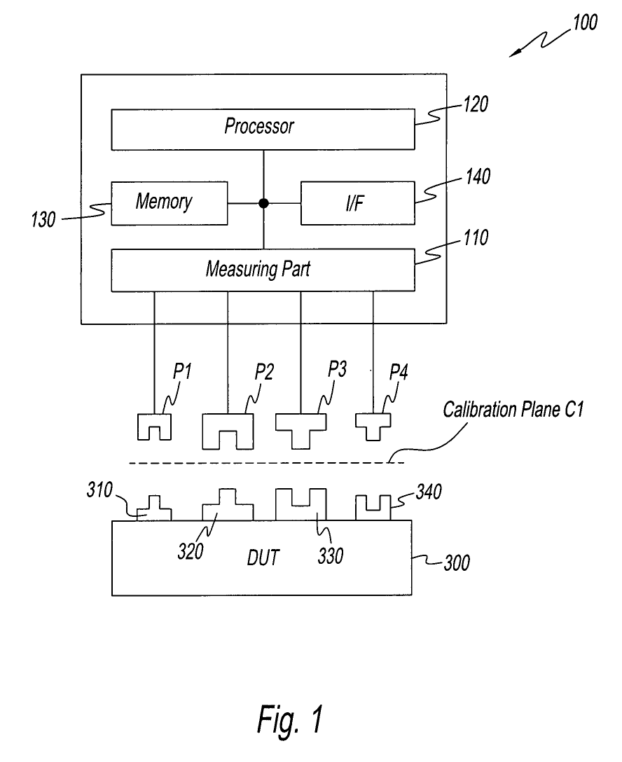

Embodiments of the present disclosure will be described while referring to the attached drawings. The first embodiment of the present disclosure is a network analyzer 100 for measuring circuit parameters such as the S parameter. Refer to FIG. 1. FIG. 1 is a drawing showing the structure of network analyzer 100. Network analyzer 100 comprises a measuring part 110, a processor 120, a memory 130, an interface 140, and test ports P1, P2, P3, and P4. The interface is referred to as the I/F in the following description and drawings. Measuring part 110 is connected to each test port P1, P2, P3, and P4, Although not illustrated, a coaxial cable, adapter, and the like are present between measuring part 110 and test ports P1, P2, P3, and P4. Measuring part 110 can supply measurement signals to any of test ports P1, P2, P3, and P4. Moreover, measuring part 110 can measure outgoing signals and incoming signals at test ports P1, P2, P3, and P4. It should be noted that outgoing signals are signals that are directed from the inside to the outside of the network analyzer. Consequently, the outgoing signals are the same as the measurement signals. Moreover, the incoming signals are signals that are directed from the outside to the inside of the network analyzer.

Processor 120 is the apparatus for performing processing, including mathematical operations and control operations. Processor 120 comprises a CPU, MPU, DSP, or a gate array that includes the same. Memory 130 is the apparatus for storing data and programs. Memory 130 comprises a hard disk drive, a removable disk drive, a semiconductor memory, and the like. I/F 140 comprises a knob, button, keyboard, mouse, display, USB interface, and LAN interface.

A DUT 300 is connected to test ports P1, P2, P3, and P4. Table 1 shows the connector specifications of P1, P2, P3, and P4, as well as the connector specifications of the corresponding ports 310, 320, 330, and 340 of DUT 300.

TABLE 1

| | | Sex |
|---|---|---|
| | Coaxial connector family | (male/female) |
| Test port P1 | 3.5 mm | Female |
| Test port P2 | N-type | Female |
| Test port P3 | N-type | Male |
| Test port P4 | 3.5 mm | Male |
| Port 310 | 3.5 mm | Male |
| Port 320 | N-type | Male |
| Port 330 | N-type | Female |
| Port 340 | 3.5 mm | Female |

It is necessary to establish a calibration plane C1 between test ports P1, P2, P3 and P4 and DUT 300 in order to measure the properties of DUT 300. It should be noted that the calibration plane is also called the reference plane.

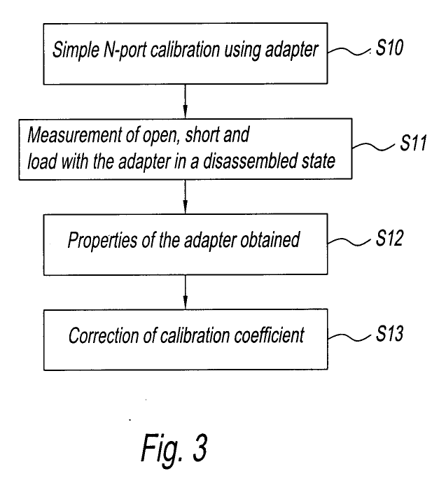

The procedure for calibrating network analyzer 100 will now be described. Refer to FIG. 1 and FIG. 3. FIG. 3 is a flow chart showing the procedure for calibrating network analyzer 100. It should be noted that the mathematical operations in each step of the flow chart are performed by processor 120.

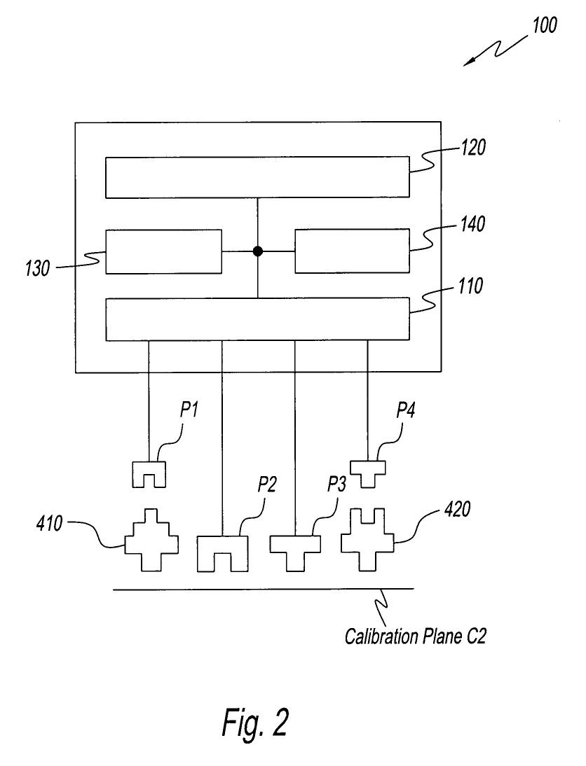

First, in step S10 simple N-port calibration is performed. N is the number of test ports (P1, P2, P3, P4) that are the subject of calibration. By means of the present embodiment, simple full four-port calibration is performed. In order to perform simple full four-port calibration by the present embodiment, an adapter 410 having a 3.5 mm (male) connector at one terminal and an N-type (male) connector at the other terminal is placed at test port P4. An adapter 420 having a 3.5 mm (female) connector at one terminal and an N-type (male) connector at the other terminal is placed at test port P4. These adapters have reciprocity. Refer to FIG. 2. FIG. 2 is a drawing showing network analyzer 100, as well as adapters 410 and 420. Moreover the through connection properties are measured between test port P1 and test port P2, test port P2 and test port P3, and test port P2 and test port P4. When the calibration in this step is performed, the calibration plane C2 is established. Another simple N-port calibration, such as simple N-port TRL calibration can be performed in this step in place of simple full N-port calibration.

Simple N-port calibration will now be discussed. Simple N-port calibration is the method whereby some of the through connection properties and line connection properties necessary for N-port calibration are omitted and the calibration coefficient is found. By means of this calibration method, the number of combinations of test ports where the through connection properties and the line connection properties should be measured is (N-1). The calibration coefficient pertaining to the omitted measurements is determined using the other calibration coefficient. For instance, transmission tracking Et relating to the omitted measurements is determined by the following formula. Here, i, j, and k show the test ports. Moreover, Et(y, x) is transmission tracking in the direction from test port x to test port y. Ed(x), Er(x), and Es(x) are the directivity, reflection tracking, and source match, respectively, at test port x on the transmitting side.

$$Et ( i , j ) = \frac{Et ( i , k ) \cdot Et ( k , f )}{Er ( k ) + Ed ( k ) \{ El ( k , j ) - Es ( k ) \}} \qquad [ \begin{matrix}Mathematical \\ formula 5\end{matrix} ]$$

The combination of test ports where the through connection properties and line connection properties are to be measured is selected such that the total formed by joining each combination by the same test port includes all of the test ports that are the subject of calibration. Consequently, for instance, any one of the following three conditions must be satisfied by the connectors of the test ports in order to conduct simple four-port calibration. (1) Three of the test port connectors are the same type and male and the one remaining test port connector is the same type and female. (2) Two test port connectors are the same type and male and the remaining two test port connectors are the same type and female. (3) Three test port connectors are the same type and female and the remaining test port connector is the same type and male. When the test port connectors do not satisfy any one of these conditions, an adapter for satisfying that any one condition becomes necessary. An adapter is used in the present embodiment in order to satisfy condition (1).

Of course, an adapter can also be used to satisfy condition (2) or (3). For instance, when an adapter is used to satisfy condition (2), adapter 410 having a 3.5 mm (male) connector at one terminal and an N-type (male) connector at the other terminal is set up at test port P1. Moreover, adapter 420 having a 3.5 mm (female) connector at one terminal and an N-type (female) connector at the other terminal is set up at test port P4. The through connection properties are measured between test port P1 and test port P2, between test port P2 and test port P3, and between test port P3 and test port P4. It is also possible to measure through connection properties between test port P1 and test port P2, test port P1 and test port P4, and test port P3 and test port P4.

In step S11, the open reference, short reference, and load reference are individually measured, with the adapter disassembled, at each test port where an adapter was used to measure the through connection properties. Specifically, the open reference, short reference, and load reference are each directly connected in succession to test port P1 and P4 and each reference is individually measured.

In step S12, the properties of the adapter used when measuring the through connection properties are found. For instance, the properties of the adapter connected to test port P1 (S11a, S12a, S21a, S22a) are found by formula 1 from the measured values obtained in step S11.

$$[ Mathematical Formula 6 ]$$

$$\begin{matrix}S 11 a = \frac{A}{det} , S 22 a = \frac{B}{det} , S 12 a = S 21 a = - \frac{C}{det} \\ where \\ [ Mathematical Formula 7 ] & ( formula 1 ) \\ det = A \cdot B - {C}^{2} & ( formula 2 ) \\ A = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{D} & ( formula 3 ) \\ B = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{D} & ( formula 4 ) \\ C = \pm \sqrt{A \cdot B + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{D}} & ( formula 5 ) \\ D = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) & ( formula 6 )\end{matrix}$$

S11a, S12a, S21a, and S22a here are the forward reflection coefficient, the forward transmission coefficient, the reverse reflection coefficient, and the reverse transmission coefficient. Moreover, S11Ms, S11Mo, and S11Ml are the measured values of the short reference, open reference, and load reference at test port P1, respectively. Furthermore, S11As, S11Ao, and S11Al are the theoretical value for S11Ms, the theoretical value for S11Mo, and theoretical value for S11Ml. The theoretical values are obtained from the defined values of the calibration kit or the property values of the ideal references.

The signs in formula 5 are defined based on the electrical length of the adapter as specified by the operator and similar means, or on the values measured in step S11 (S12a or S21a). For instance, when the symbols are determined based on the specified electrical length, first the phase is found by multiplying the angular velocity of the measured signal by the delay time calculated from the electrical length. The value in formula 5 when the sign is positive or the value in formula 5 when the sign is negative is selected based on which is closer to the pre-determined phase value. Moreover, when the sign is determined based on the measured value, the sign is determined based on the phase continuity of the measured value within the measured frequency range. First, the measured value is found within the measurement frequency range using either the positive or negative sign. If the phase deviates by a predetermined value or greater between adjacent measurement points, it is concluded that phase is not continuous and that the incorrect sign was selected there. In such a case, the sign is reversed and the measured value is found.

Finally, in step S13, the calibration coefficient obtained by the calibration in step S10, which should establish the calibration plane C1, is corrected. In essence, the adapter properties found in step S12 are removed from the calibration coefficient obtained by calibration in step S10. Disassembling the adapter is the same as adding a two-terminal-pair circuit having the reverse properties of the adapter properties. The calibration coefficient is corrected based on this concept. In essence, the reverse properties of the adapter property found in step S12 are added to the calibration coefficient obtained by calibration in step S10. It should be noted that the calibration coefficient is also called the error coefficient. The two-terminal-pair circuit having the reverse properties of the adapter properties is simply referred to as the anti-adapter hereafter.

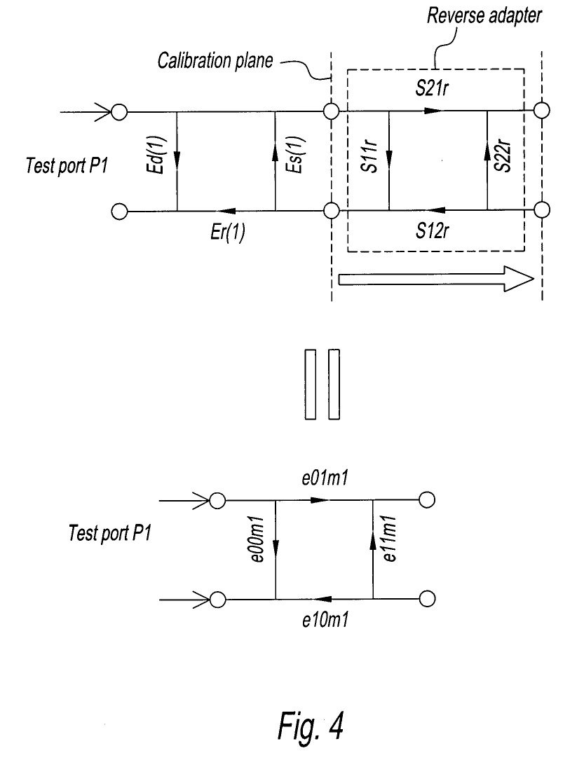

For instance, when the properties of the adapter connected to test port P1 are removed from the calibration coefficient, the calibration coefficient is corrected as follows. First, the correction of the calibration coefficient in an error model, wherein test port P1 is the transmission port, will be described. Refer to FIG. 4. FIG. 4 is a drawing showing the signal flow when the anti-adapter is connected to the transmission port. Ed(1), Er(2), and Es(1) are the calibration coefficients obtained by the calibration in step S10 on the transmission side when the transmitting port is test port P1. Ed(1), Er(1) and Es(1) are directivity, reflection tracking, and source match, respectively. Coefficients not used in the description are omitted from FIG. 4.

The properties of the anti-adapter (S11r, S12r, S21r, S22r) are as shown in formula 7.

### [Mathematical Formula 8]

S11r=A, S22r=B, S12r=S21r=C (formula 7)

When the properties of the anti-adapter and the calibration coefficient on the transmission side obtained by the calibration in step S10 are combined, the coefficient represented by formula 8 is obtained.

$$[ Mathematical formula 9 ]$$

$$\begin{matrix}Em 1 = ( \begin{matrix}e 00 m 1 & e 01 m 1 \\ e 10 m & e 11 m 1\end{matrix} ) \\ = ( \begin{matrix}Ed ( 1 ) + \frac{Er ( 1 ) \cdot S 11 r}{1 - Es ( 1 ) \cdot S 11 r} & \frac{Er ( 1 ) \cdot S 12 r}{1 - Es ( 1 ) \cdot S 11 r} \\ \frac{S 21 r}{1 - Es ( 1 ) \cdot S 11 r} & S 22 r + \frac{Es ( 1 ) \cdot S 21 r \cdot S 12 r}{1 - Es ( 1 ) \cdot S 11 r}\end{matrix} )\end{matrix} \qquad ( formula 8 )$$

(Formula 8)

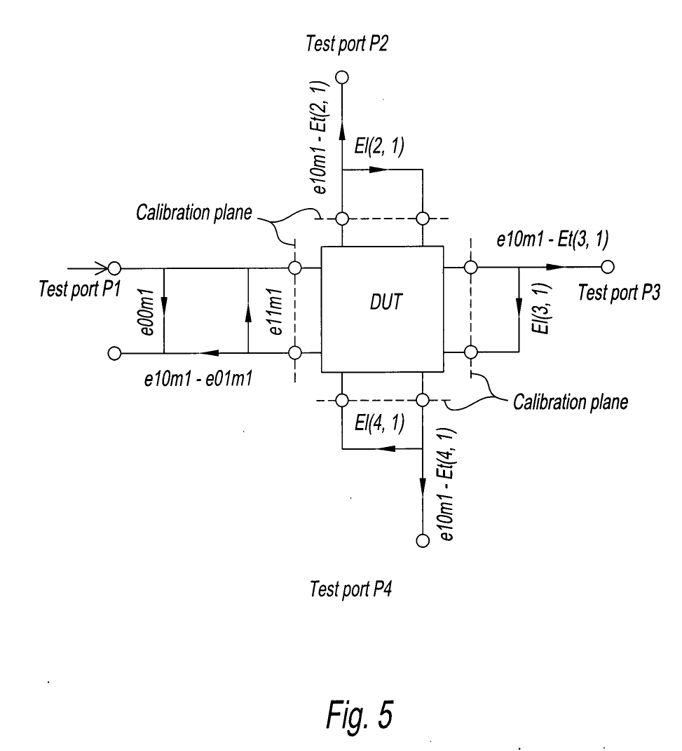

The coefficient represented by formula 8 is used in a 48-item error model. Refer to FIG. 5, which shows the results that were used. FIG. 5 is a drawing showing the signal flow of the 48-item error model when the anti-adapter is connected to the transmission port. As in FIG. 4, the transmission port is test port P1. El(2, 1), El(3,1), El(4, 1), Et(2, 1), Et(3, 1) and Et(4,1) in FIG. 5 are the calibration coefficients obtained by the calibration in step S10 on the receiving side when the transmitting port is test port P1. El(2, 1) is the load match between test port P1 and test port P2. El(3,1) is the load match between test port P1 and test port P3. El(4,1) is the load match between test port P1 and test port P4. Et (2, 1) is transmission tracking between test port P1 and test port P2. Et (3, 1) is transmission tracking between test port P1 and test port P3. Et (4, 1) is transmission tracking between test port P1 and test port P4. The coefficients not used in the description are omitted from FIG. 5.

As is clear from the signal flow in FIG. 5, the following formulas represent the new calibration coefficients (Ed_{new}, Er_{new}, Es_{new}, Et_{new}, El_{new}) that are obtained by adding the properties of the anti-adapter to the calibration coefficients obtained by the calibration in step S10.

$$[ Mathematical Formula 10 ]$$

$$\begin{matrix}{Ed}_{new} ( 1 ) = e 00 m 1 = Ed ( 1 ) + \frac{Er ( 1 ) \cdot S 11 r}{1 - Es ( 1 ) \cdot S 11 r} & ( formula 9 ) \\ {Es}_{new} ( 1 ) = e 11 m 1 = S 22 r + \frac{Es ( 1 ) \cdot S 21 r \cdot S 12 r}{1 - Es ( 1 ) \cdot S 11 r} & ( formula 10 ) \\ {Er}_{new} ( 1 ) = e 10 m 1 \cdot e 01 m 1 = \frac{Er ( 1 ) \cdot S 21 r \cdot S 12 r}{{( 1 - Es ( 1 ) \cdot S 11 r )}^{2}} & ( formula 11 ) \\ {Et}_{new} ( 2 , 1 ) = e 10 m 1 \cdot Et ( 2 , 1 ) = \frac{Et ( 2 , 1 ) \cdot S 21 r}{1 - Es ( 1 ) \cdot S 11 r} & ( formula 12 ) \\ {Et}_{new} ( 3 , 1 ) = e 10 m 1 \cdot Et ( 3 , 1 ) = \frac{Et ( 3 , 1 ) \cdot S 21 r}{1 - Es ( 1 ) \cdot S 11 r} & ( formula 13 ) \\ {Et}_{new} ( 4 , 1 ) = e 10 m 1 \cdot Et ( 4 , 1 ) = \frac{Et ( 4 , 1 ) \cdot S 21 r}{1 - Es ( 1 ) \cdot S 11 r} & ( formula 14 ) \\ {El}_{new} ( 2 , 1 ) = El ( 2 , 1 ) & ( formula 15 ) \\ {El}_{new} ( 3 , 1 ) = El ( 3 , 1 ) & ( formula 16 ) \\ {El}_{new} ( 4 , 1 ) = El ( 4 , 1 ) & ( formula 17 )\end{matrix}$$

Ed_{new}(1), Es_{new}(1), and Er_{new}(1) are directivity, source match, and reflection tracking, respectively. Moreover, Et_{new}(2, 1), Et_{new} (3,1) and Et_{new} (4,1) are transmission tracking. El_{new} (2,1), El_{new} (3,1), and El_{new} (4,1) are load match. The numbers in parentheses represent the related test ports. For instance, El_{new}(2,1) is the new load match between test port P1 and test port P2.

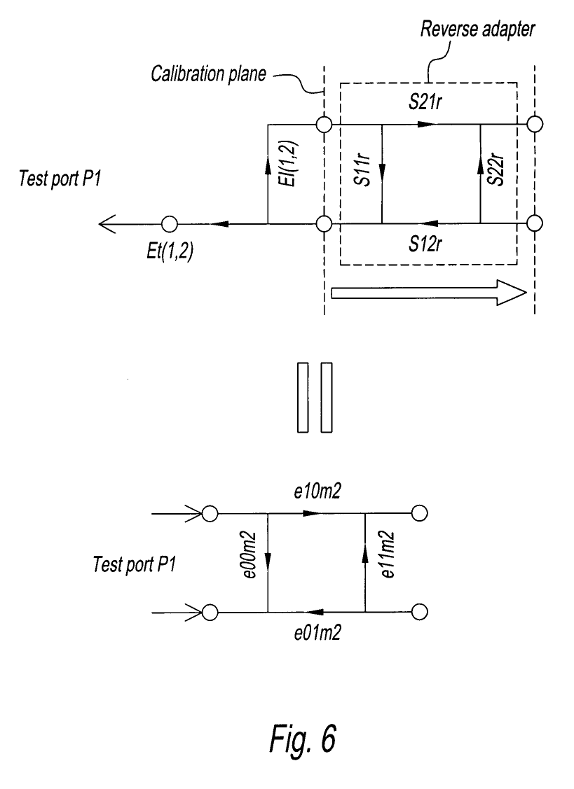

The correction of the calibration coefficient in the error model, where test port P1 is the receiving port, will now be described. Refer to FIG. 6. FIG. 6 is the drawing showing the signal flow when the transmitting port is test port P2. The anti-adapter is connected to test port 1. Et(1,2) and El(1,2) in FIG. 6 are the calibration coefficients obtained by the calibration in step S10 on the receiving side when the transmitting port is test port P2. Et(1, 2) and El (1,2) are the transmission tracking and load match, respectively. The coefficients not used in the description are omitted from FIG. 6.

When the properties of the anti-adapter and the calibration coefficient on the receiving side obtained by the calibration in step S10 are combined, the coefficient represented by formula 18 is obtained.

$$[ Mathematical Formula11 ]$$

$$Em 2 = ( \begin{matrix}e 00 m 2 & e 01 m 2 \\ e 10 m 2 & e 11 m 2\end{matrix} ) ( \begin{matrix}0 & \frac{Et ( 1 , 2 ) \cdot S 12 r}{1 - El ( 1 , 2 ) \cdot S 11 r} \\ 0 & S 22 a + \frac{El ( 1 , 2 ) \cdot S 21 r \cdot S 12 r}{1 - El ( 1 , 2 ) \cdot S 11 r}\end{matrix} ) \qquad ( formula 18 )$$

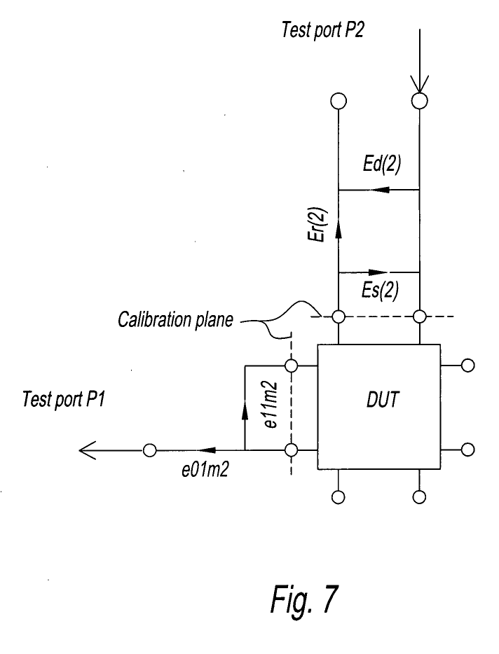

The coefficient represented by formula 18 is used in a 48-item error model. Refer to FIG. 7, which shows the results that were used. FIG. 7 is a drawing showing the signal flow of the 48-item error model when the anti-adapter is connected to the receiving port. As in FIG. 6, the transmitting port is test port P2. Ed(2), Er(2), and Es(2) in FIG. 7 are the calibration coefficients obtained by the calibration in step S10 on the transmission side when the transmitting port it is test port P2. Ed(2), Er(2), and Es(2) are directivity, reflection tracking, and source match, respectively. The coefficients not used in the description are omitted from FIG. 7.

As is clear from the signal flow in FIG. 7, the following formulas represent the new calibration coefficients (Ed_{new}, Er_{new}, Es_{new}, Et_{new}, El_{new}) obtained by removing the adapter properties found in step S12 from the calibration coefficients obtained by the calibration in step S10.

$$\begin{matrix}{Ed}_{new} ( 2 ) = Ed ( 2 ) & ( formula 19 ) \\ {Es}_{new} ( 2 ) = Es ( 2 ) & ( formula 20 ) \\ {Er}_{new} ( 2 ) = Er ( 2 ) & ( formula 21 ) \\ {Et}_{new} ( 1 , 2 ) = e 01 m 2 = \frac{Et ( 1 , 2 ) \cdot S 12 r}{1 - El ( 1 , 2 ) \cdot S11r} & ( formula 22 ) \\ {El}_{new} ( 1 , 2 ) = e 11 m 2 = S 22 r + \frac{El ( 1 , 2 ) \cdot S 21 r \cdot S 12 r}{1 - El ( 1 , 2 ) \cdot S 11 r} & ( formula 23 )\end{matrix}$$

Es_{new}(2), Et_{new}(1,2), and El_{new}(1,2) are directivity, reflection tracking, source match, transmission tracking, and load match, respectively. It goes without describing that the numbers in parentheses represent the related test ports. For instance, El_{new}(1,2) is the load match between test port P1 and test port P2.

The above-mentioned correction method in the present step can be similarly applied to other test ports and calibration coefficients. The calibration coefficients on both the transmitting side and the receiving side are affected by the properties of the adapter in the model wherein the test port connected to the adapter is the transmitting port. In this case, the same correction method as in formulas 9 through 17 can be used. Moreover, the calibration coefficient on the receiving side is affected by the adapter properties in the models wherein this test port is the receiving port. In this case, the same correction method as in formulas 19 through 23 can be used.

For instance, transmission tracking and load match are affected by adapter properties in error models wherein the transmitting port is test port P3 and the receiving port is test port P1. In this case, the same correction method as in formulas 22 and 23 can be used. In essence, the corrected calibration coefficient is represented by the following formulas.

$$[ Mathematical Formula 13 ]$$

$$\begin{matrix}{Et}_{new} ( 1 , 3 ) = e 01 m 3 = \frac{Et ( 1 , 3 ) \cdot S 12 r}{1 - El ( 1 , 3 ) \cdot S 11 r} & ( formula 24 ) \\ {El}_{new} ( 1 , 3 ) = e 11 m 3 = S 22 r + \frac{El ( 1 , 3 ) \cdot S 21 r \cdot S 12 r}{1 - El ( 1 , 3 ) \cdot S 11 r} & ( formula 25 )\end{matrix}$$

Et(1,3) and El(1,3) are the calibration coefficients obtained by the calibration in step S10 on the receiving side when the transmitting port is test port P3. Et(1,3) and El(1, 3) are the transmission tracking and load match, respectively.

The above description has described step S13. Although not shown in a flow chart, the corrected calibration coefficient obtained in step S13 is stored in memory 130 or similar device, and is referred to for error correction during measurement. By means of the present embodiment, the measurements necessary for correction are full four-port correction of one set and OSL (Open, Short, Load) measurements of two sets. On the other hand, when the conventional adapter removal method was applied to the same network analyzer, full two-port calibration of ten sets was necessary. The preceding is a description of the first embodiment.

However, by means of the first embodiment, the N-port calibration can be an N-port calibration using an electronic calibration module instead of N-port calibration by the simple N-port calibration method. An embodiment of this change will now be described as a second embodiment of the present disclosure.

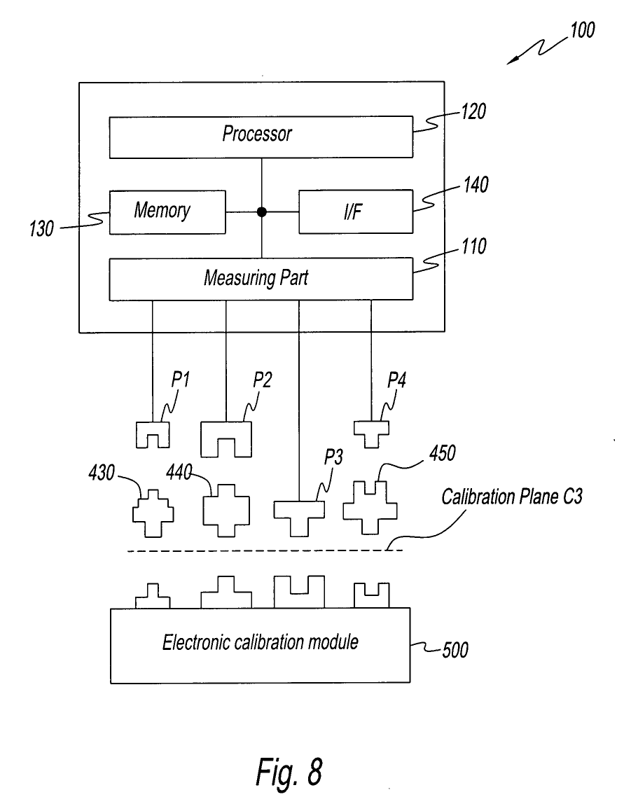

Refer to FIG. 8. FIG. 8 is a drawing showing network analyzer 100 and an electronic calibration module 500. The same reference numbers as in FIG. 1 are used in FIG. 8 for the structural elements that are the same as in FIG. 1, and a description thereof has been omitted. Electronic calibration module 500 is a calibration apparatus having an impedance state that is highly programmable and reproducible. Electronic calibration module 500 is the “Agilent (registered trademark) E4431B” or similar device. By means of the present embodiment, electronic calibration module 500 has four ports and the connector of each port is an N-type connector (female). As in the first embodiment, a calibration plane C1 (FIG. 1) must be established between test ports P1, P2, P3, and P4 and DUT 300 in order to measure the properties of DUT 300.

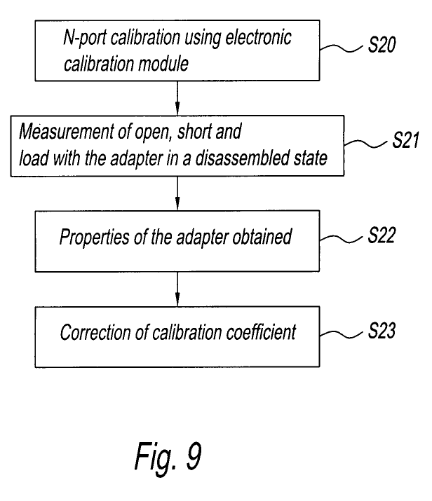

Next, the procedure for calibrating network analyzer 100 will be described. Refer to FIG. 8 and FIG. 9. FIG. 9 is a flow chart showing the procedure for calibrating network analyzer 100. It should be noted that the mathematical operations in each step of the flow chart are performed by processor 120.

First, in step S20, N port calibration is performed using an electronic calibration module. N is the number of test ports (P1, P2, P3, and P4) that are the subject of calibration. By means of the present embodiment, full four-port calibration is performed. When N-port calibration is performed using electronic calibration module 500, there is no need for an adapter for electrically connecting the test ports to one another. Instead, each test port has an adapter for connection with the connector of electronic calibration module 500. Consequently, by means of the present embodiment, test port P1 has an adapter 430 with a 3.5 mm (male) connector at one terminal and an N-type (male) connector at the other terminal. Moreover, test port P2 has an adapter 440, which has an N-(male) connector at both terminals. Test port P4 has an adapter 450, which has a 3.5 mm (female) connector at one terminal and an N-type (male) connector at the other terminal. These adapters have reciprocity. Moreover, through connection is performed to via electronic calibration module 500. When the calibration of this step is performed, a calibration plane C3 is established.

Next, in step S21, the open reference, short reference, and load reference are individually measured at each test port with the adapter in a disassembled state. Specifically, the open reference, short reference, and load reference are directly connected in succession to each of test ports P1, P2, and P4, and each reference is individually measured.

Next, in step S22, the properties of each adapter are found. By means of this step, the properties of each adapter are found by the same procedure as in step S12. For instance, the properties of the adapter connected to test port P1 (S11a, S12a, S21a, S22a) are found by formula 1 from the values measured in step S11. Refer to the description of step S12 for the details.

Finally, in step S23, the calibration coefficient obtained by the calibration in step S20, which should establish calibration plane C1 (FIG. 1) is corrected. By means of this step, the calibration coefficient is corrected by the same procedure as in step S13. In essence, the adapter properties found in step S22 are removed from the calibration coefficient obtained by the calibration in step S20.

Although not shown in the flow chart, the corrected calibration coefficients obtained in step S23 is stored in memory 130 or similar device, and are referred to for error correction during measurement. The preceding is a description of the second embodiment.

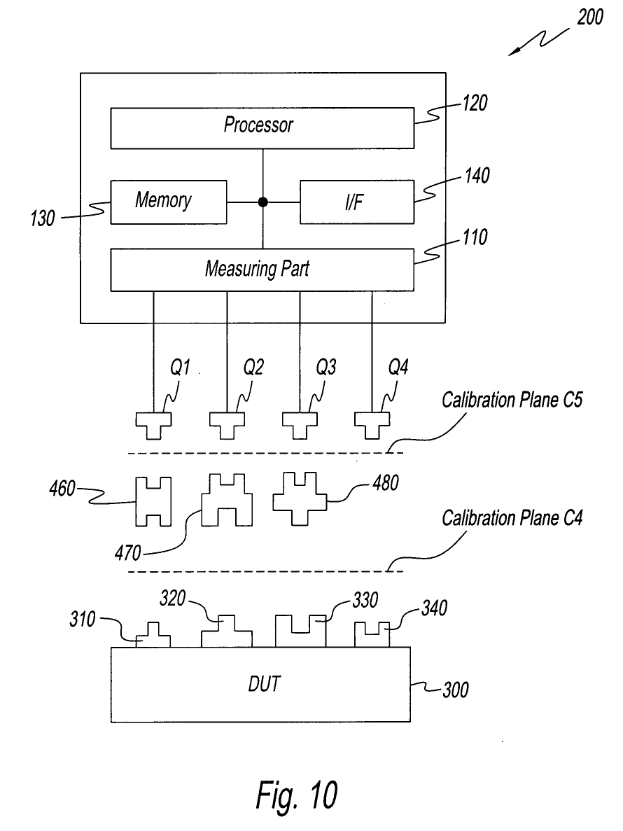

A third embodiment of the present disclosure will now be described. The third embodiment differs from the first embodiment in that the connectors of the test ports are all the same but adapters are used when DUT 300 is measured. The third embodiment is a network analyzer 200 for measuring the circuit parameters, such as the S parameter. Refer to FIG. 10 below. FIG. 10 is a drawing showing the structure of network analyzer 200. The same reference numbers as in FIG. 1 are used for the structural parts in FIG. 10 that are the same as in FIG. 1, and a description thereof has been omitted. Network analyzer 200 comprises measuring part 110, processor 120, memory 130, interface 140, and test ports Q1, Q2, Q3, and Q4. Measuring part 110 is connected to each of test ports Q1, Q2, Q3, and Q4. The connector specifications of test ports Q1, Q2, Q3, and Q4 are shown in Table 2.

TABLE 2

| | | Sex |
|---|---|---|
| | Coaxial connector family | (male/female) |
| Test port Q1 | 3.5 mm | Male |
| Test port Q2 | 3.5 mm | Male |
| Test port Q3 | 3.5 mm | Male |
| Test port Q4 | 3.5 mm | Male |

Test ports Q1, Q2, Q3, and Q4 are connected to DUT 300 via measurement adapters 460, 470, and 480. It should be noted that adapter 460 has a 3.5 mm (female) connector at both terminals. Adapter 470 has a 3.5 mm (female) connector at one terminal and an N-type (female) connector at the other terminal. Adapter 480 has a 3.5 mm (female) connector at one terminal and an N-type connector (male) connector at the other terminal. These adapters have reciprocity. A calibration plane C4 must be established between test ports Q1, Q2, Q3, and Q4 in order to measure the properties of DUT 300.

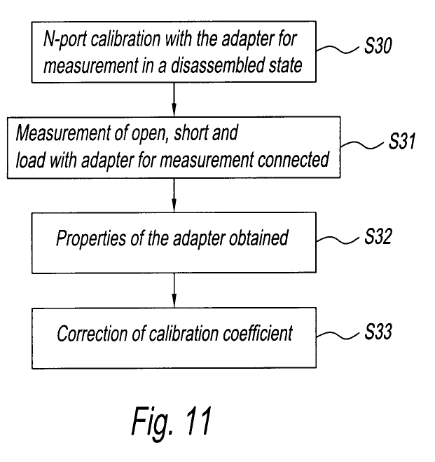

Next, the procedure for calibrating network analyzer 200 will now be described. Refer to FIG. 10 and FIG. 11. FIG. 11 is a flow chart showing the procedure for calibrating network analyzer 200. The mathematical operations in each step of the flow chart are performed by processor 120.

First, in step S30, N-port calibration is performed on the test ports. N is the number of test ports (P1, P2, P3, P4) that are the subject of calibration. By means of the present embodiment, full four-port calibration is performed on test ports Q1, Q2, Q3, and Q4. As is clear from Table 2, the test ports cannot be directly connected to one another. Consequently, when the through connection properties are measured during full four-port calibration, the test ports are connected to one another via an adapter for calibration having a 3.5 mm (female) connector at both terminals. When the properties of the adapter for calibration are unknown, the calibration can be performed by the correction method described in the first embodiment (series of procedures in steps S10 through S13, or the series of procedures for the second embodiment in steps S20 through S23). If the connector of the adapter for calibration is known, only above-mentioned steps S10 and S13 should be performed. When the calibration of this step is performed, a calibration plane C5 is established.

Next, in step S31, the open reference, short reference, and load reference are individually measured with the adapter for measurement connected. Specifically, the adapter necessary for connecting and measuring DUT 300 is connected to the test port, the open reference, short reference, and load reference are connected in succession to the end of this adapter, and each reference is measured at this test port. In short, the open reference, short reference, and load reference at each of test ports Q1, Q2, Q3, and Q4 are measured in succession with the adapter connected. It should be noted that adapter 460 is connected to test port Q1, adapter 470 is connected to test port Q2, and adapter 480 is connected to test port Q3.

Next, in step S32, the properties of the adapter used to connect and measure DUT 300 are found. For instance, the properties of the adapter 460 (S11w, S12w, S21w, S22w) are found by formula 26 from the values measured in step S31. A, B, and C in the formula are as defined previously.

[Mathematical formula 14]

S11w=A, S22w=B, S12w=S21w=C (formula 26)

Finally, in step S33, the calibration coefficient obtained by the calibration in step S30 is corrected. In essence, the properties of the adapter for measurement found in step S32 are added to the calibration coefficient obtained by the calibration in step S30. Correction of the calibration coefficient in this step can be performed by the same procedure as used for correction in above-mentioned step S13. For instance, when the properties of adapter 460 found in step S32 are added to the calibration coefficient obtained by calibration in step S30, S11r is read as S11w, S12r is read as S12w, S21r is read as S21w, and S22r is read as S22w.

When the properties of each adapter for measurement are added to the calibration coefficient, a calibration plane C4 is established between DUT 300 and adapters 460, 470, and 480, as well as test port Q4. Moreover, although not shown in the flow chart, the corrected calibration coefficient obtained in step S33 is stored in memory 130 or similar device, and referred to for error correction during measurement. The preceding is a description of the third embodiment.

The above-mentioned three embodiments can be modified as follows. First, modification is possible such that in step S12 the properties of the anti-adapter can be found rather than finding the properties of the adapter. In this case, a mathematical operation for finding the properties of the anti-adapter in step S13 is unnecessary. Moreover, the same mathematical operation can be used for correction in the second embodiment and for correction in the third embodiment. This is clear from formulas 7 and 26. Both formulas represent the properties of a two-terminal-pair circuit obtained from the measured values of the open reference, short reference, and load reference in the same specific test ports after full N-port calibration. It is clear that the two formulas are the same.

The three embodiments have described a four-port environment. However, the present disclosure is not limited to a four-port environment, and can be similarly apply to an environment of two ports, three ports, or five or more ports. In short, the present disclosure can be used in network analyzers having two or more ports.

What is claimed is:

1. A method for calibrating a network analyzer having two or more test ports, said calibration method comprising:
preparing an adaptor of unknown properties necessary for conducting N port calibration;
conducting N port calibration using the adaptor;
measuring, with the adaptor in a disassembled state, the open reference, short reference, and load reference at the test port to which the adaptor was connected during said calibration; and
correcting the calibration coefficient obtained by said calibration using the adaptor properties found from the measured values of the open reference, short reference, and load reference,
wherein N is an integer of two or greater.

2. The calibration method according to claim 1, wherein in said calibration coefficient is corrected by adding to the calibration coefficient the properties of circuit with two terminal pairs (S11a, S12a, S21a, S22a) as represented by the following formula:
$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{( det )} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula 1\end{matrix} ]$$
wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

3. A method for calibrating a network analyzer having three or more test ports, said calibration method comprising:
preparing an adaptor of unknown properties necessary for conducting simple N port calibration;
conducting simple N port calibration using the adaptor;
measuring, with the adaptor in a disassembled state, the open reference, short reference, and load reference at the test port to which the adaptor was connected during said calibration; and
correcting the calibration coefficient obtained by said calibration using the adaptor properties found from the measured values of the open reference, short reference, and load reference,
wherein N is an integer of three or greater.

4. The calibration method according to claim 3, wherein in said calibration coefficient is corrected by adding to the calibration coefficient the properties of circuit with two terminal pairs (S11a, S12a, S21a, S22a) as represented by the following formula:
$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula 1\end{matrix} ]$$
wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

5. A method for calibrating a network analyzer having two or more test ports, said calibration method comprising:
preparing an electronic calibration module;
preparing an adaptor of unknown properties that serves to connect to a port of the electronic calibration module the test ports that cannot be directly connected;
conducting N port calibration using the adaptor and the electronic calibration module;
measuring, with the adaptor in a disassembled state, the open reference, short reference, and load reference at the test port to which the adaptor was connected during said calibration; and
correcting the calibration coefficient obtained by said calibration using the adaptor properties found from the measured values of the open reference, short reference, and load reference,
wherein N is an integer of two or greater.

6. The calibration method according to claim 5, wherein in said calibration coefficient is corrected by adding to the calibration coefficient the properties of circuit with two terminal pairs (S11a, S12a, S21a, S22a) as represented by the following formula:
$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula \end{matrix} ]$$
wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

7. A method for calibrating a network analyzer having two or more test ports, said calibration method comprising:
preparing an adaptor of unknown properties that serves to connect to a port of the device under test the test ports for measuring the device under test that cannot be directly connected;
conducting N port calibration with the adaptor in a disassembled state from the test port;
measuring, with the adaptor in an assembled state, the open reference, short reference, and load reference at the test port for which the adaptor is prepared; and
correcting the calibration coefficient obtained by said calibration using the adaptor properties found from the measured values of the open reference, short reference, and load reference,
wherein N is an integer of two or greater.

8. The calibration method according to claim 7, wherein in said calibration coefficient is corrected by adding to the calibration coefficient the properties of circuit with two terminal pairs (S11a, S12a, S21a, S22a) as represented by the following formula:
$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula \end{matrix} ]$$
wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.

9. A network analyzer having two or more test ports, said network analyzer comprising:
a mathematical operator for finding the properties of the two-terminal-pair circuit from the results of measuring the open reference, short reference, and load reference of the test port where N port calibration has been conducted,
wherein N is an integer of two or greater.

10. The network analyzer according to claim 9, wherein said N port calibration is simple N port calibration or N port calibration using an electronic calibration module.

11. The network analyzer according to claim 9, wherein in said calibration coefficient is corrected by adding to the calibration coefficient the properties of circuit with two terminal pairs (S11a, S12a, S21a, S22a) as represented by the following formula:
$$S 11 a = \frac{\begin{matrix}\begin{matrix}S 11 Mo \cdot S 11 Ao ( S 11 Ms \cdot S 11 A l - S 11 As \cdot S 11 Ml ) + \\ S 11 Ms \cdot S 11 As ( S 11 Ml \cdot S 11 Ao - S 11 Al \cdot S 11 Mo ) +\end{matrix} \\ S 11 Ml \cdot S 11 Al ( S 11 Mo \cdot S 11 As - S 11 Ao \cdot S 11 Ms )\end{matrix}}{det} \\ S 22 a = \frac{\begin{matrix}S 11 Mo ( S 11 Al - S 11 As ) + \\ S 11 Ms ( S 11 Ao - S 11 Al ) + \\ S 11 Ml ( S 11 As - S 11 Ao )\end{matrix}}{det} \\ \begin{matrix}S 12 a = S 21 a \\ = \pm \sqrt{S 11 a \cdot S 22 a + \frac{\begin{matrix}\begin{matrix}S 11 Mo \cdot S 11 Ao ( S 11 Ml - S 11 Ms ) + \\ S 11 Ms \cdot S 11 As ( S 11 Mo - S 11 Ml ) +\end{matrix} \\ S 11 Ml \cdot S 11 Al ( S 11 Ms - S 11 Mo )\end{matrix}}{det}}\end{matrix} \\ det = S 11 Mo \cdot S 11 Ao ( S 11 Al - S 11 As ) + S 11 Ms \cdot S 11 As ( S 11 Ao - S 11 Al ) + S 11 Ml \cdot S 11 Al ( S 11 As - S 11 Ao ) \qquad [ \begin{matrix}Mathematical \\ formula \end{matrix} ]$$
wherein S11Ms, S11Mo, and S11Ml are the measured value of the short reference, the measured value of the open reference, and the measured value of the load reference, respectively, at the test port relating to the adaptor, and S11As, S11Ao, and S11Al are the theoretical value for the measured value of the short reference, the theoretical value for the measured value of the open reference, and the theoretical value for the measured value of the load reference, respectively.
